(19) United States
(12) Patent Application Publication
(10) Pub. No.: US 2021/0354982 A1
(43) Pub. Date: Nov. 18, 2021

(54) Method for Fabrication of a Suspended Elongated Structure by Etching or Dissolution Through Openings in a Layer

(71) Applicants: Arne Quellmalz, Stockholm (SE); Kristinn B. Gylfason, Solna (SE); Floria Ottonello Briano, Stockholm (SE)

(72) Inventors: Arne Quellmalz, Stockholm (SE); Kristinn B. Gylfason, Solna (SE); Floria Ottonello Briano, Stockholm (SE)

(21) Appl. No.: 17/281,837

(22) PCT Filed: Mar. 8, 2019
(86) PCT No.: PCT/SE2019/050207

§ 371 Date: Mar. 31, 2021

(30) Foreign Application Priority Data
Mar. 14, 2018 (SE) 1850284-9

(51) Int. Cl. B81C 1/00; H01L 21/306; G01N 21/3504; G02B 6/136

(52) U.S. Cl. CPC B81C 1/00539; H01L 21/30604; G02B 2006/12176; G02B 6/136; G01N 21/3504

(57) ABSTRACT

In an embodiment a device includes a base layer, a support structure formed on the base layer, a side structure formed on the base layer and an elongated structure extending in a length direction in a device layer, wherein the elongated structure has a width in the device layer in a direction perpendicular to a length direction and a height in a direction out of the device layer and perpendicular to the length direction, wherein the elongated structure is delimited by two side surfaces and is supported on the support structure, and wherein at least a part of the side structure is arranged at a distance from the elongated structure in a width direction.

This patent application is a national phase filing under section 371 of PCT/SE2019/050207, filed Mar. 8, 2019, which claims the priority of Swedish patent application 1850284-9, filed Mar. 14, 2018, each of which is incorporated herein by reference in its entirety.

### TECHNICAL FIELD

The invention relates to a method for fabrication of a device with an elongated structure supported by a support structure.

### BACKGROUND

Optical sensing using the absorption bands of various gases in the visible or infrared (IR) wavelength range is an established method. The absorption may be measured in cavities with mirrors, in order to achieve an effective interaction length which is longer than the physical size of the cavity. This approach is limited by the optical losses in the mirrors. For IR, the source is often a broadband incandescent lamp. To get a spectral resolution, optical spectral analysis is then needed. Detectors can be thermal or semiconductor-based photon detectors.

To make sensitive devices with a long optical path-length, either high quality mirrors must be used or the physical path, and hence the device size, must be long. For many applications, low gas flows and the large volume of the gas chamber limit the response speed of the sensor.

International Patent Application Publication WO 2017/003353 describes a sensor device for detecting a component in a fluid such as a gas. The sensor device comprises a planar substrate, a waveguide for guiding an electromagnetic wave and a support structure extending from the substrate to the waveguide. A method for detecting a component in a gas comprises the steps of providing the waveguide in contact with the gas, transmitting an electromagnetic wave into a first portion of the waveguide, allowing the electromagnetic wave to interact with the fluid in a region of an evanescent wave of the electromagnetic wave around the waveguide and detecting the electromagnetic wave at a second portion of the waveguide. The component in the gas is determined based on the detected electromagnetic wave at the second portion. The width of the support structure varies along the length direction of the waveguide and the waveguide is of a material of a first composition and the support structure is of a material of a second composition. In this way the influence of the support structure on the waveguiding properties is decreased. In order to minimize the influence of the support structure on the waveguiding properties and to increase the sensitivity of the sensor device it is advantageous to have the waveguide partly free-hanging. It may, however be complicated to fabricate such a sensor device, especially if a light source and a detector is to be integrated with the waveguide in an integrated circuit.

Apart from a light source and a detector it might also be desirable to include electronics for driving of the light source and electronics for readout from the detector.

Apart from a sensor device, also other devices may be contemplated which comprise an elongated structure extending in a length direction in a device layer and being supported on a first layer by a support structure.

### SUMMARY

Embodiments provide a method for fabrication of a device with an elongated structure extending in a length direction in a device layer, the elongated structure having a width in the device layer in a direction perpendicular to the length direction, and a height in a direction out of the device layer and perpendicular to the length direction, being delimited by two side surfaces and being supported on a first layer by a support structure, which method is an alternative to the methods of the prior art.

Other embodiments provide a method for fabrication of a device with an elongated structure extending in a length direction in a device layer, the elongated structure having a width in the device layer in a direction perpendicular to the length direction, and a height in a direction out of the device layer and perpendicular to the length direction, being delimited by two side surfaces and being supported on a first layer by a support structure, which method extends the possibilities for additional process steps after suspension of the elongated structure.

The methods of the prior art for fabrication of an elongated structure such as a waveguide as described in International Patent Application Publication WO 2017/003353 makes it difficult to integrate additional components on the same chip as the waveguide. This is due to the fact that contact with aqueous solutions damages the waveguides. This makes it impossible to apply wet etching, spin-coating, material transfer and other processes to the chip after the suspension of the waveguide. Furthermore, the suspension of a waveguide as described in International Patent Application Publication WO 2017/003353 requires aggressive etchants which are not compatible with most materials. This makes it difficult to fabricate a device before suspension of the waveguide.

According to a first aspect a method is provided for fabrication of a device with an elongated structure, extending in a length direction in a device layer, the elongated structure having a width in the device layer in a direction perpendicular to the length direction, and a height in a direction out of the device layer and perpendicular to the length direction, being delimited by two side surfaces and being supported on a planar first layer by a support structure. The method comprises the step of providing a planar first layer on which the device layer is supported. The method also comprises the step of removing material in the device layer to provide a first set of openings through the device layer. The method also comprises the step of removing material by etching or dissolution from the planar first layer under the elongated structure through the first set of openings, wherein the arrangement of the first set of openings is such that said support structure is formed on which the elongated structure is supported. The method also comprises the step of removing material from the device layer to form the elongated structure delimited by the side surfaces.

With regard to the first layer it is normally planar and flat before microfabrication processing. However, during processing and before application of the device layer material may be removed from the planar first layer resulting in a surface of the planar first layer which is not perfectly flat.

The method provides an alternative to the methods of the prior art and allows additional process steps to be performed after the suspension as the elongated structure is supported to the rest of the device layer between the openings in the device layer.

The method allows the fabrication of additional integrated devices after suspension of the elongated structure. Thus, the aggressive etchants used to remove material from under the device layer may be used before the fabrication of additional devices. As no special precautions have to be taken during fabrication of the device it is possible to use batch processing on a wafer to fabricate a number of devices simultaneously.

The method may also comprise, after the step of removing material from the planar first layer under the elongated structure and before the step of removing the material in the device layer between the openings of the first set of openings, performing additional processing steps including photolithography and/or material deposition and/or thermal processing and/or surface functionalization and/or layer transfer processes and/or wet and dry etching.

The elongated structure may have a first and a second end, but it is also possible to have the elongated structure in the form of a closed loop.

It is also possible to perform additional process steps before the removal of material in the device layer or before removal of material from the planar first layer under the elongated structure provided that said process steps are compatible with the removal of material from the planar first layer.

The most important advantages with the method are achieved when the material in the planar first layer requires aggressive etchants, which are not compatible with other process steps. With the method such other process steps may be performed after removal of material from the planar first layer.

In contrast to the methods according to the prior art it is not necessary to vary the width of the waveguide in order to provide a support structure in the form of pillars. The support pillars can be shaped independently from the width of the waveguide itself. This enables the elimination of losses which occur in waveguides fabricated with methods according to the prior art due to large pillars and mode matching between thin and wide waveguide modes.

The method is primarily intended for fabrication of a device with an elongated structure supported by a planar first layer, wherein the elongated structure is a waveguide. However, the invention may also be used for fabrication of devices with elongated structures to be used in other applications.

An additional layer may be arranged between the device layer and the planar first layer. In case such an additional layer is arranged between the device layer and the planar first layer the openings of the first set of openings are arranged also through the additional layer. The additional layer has the function of a protective layer during the step of removing material from the planar first layer under the elongated structure. By the addition of the additional layer as a protective layer it is possible to have the same material in the planar first layer as in the device layer.

The material in the additional layer may be chosen from a polymer, silicon dioxide, silicon nitride and sapphire. Also, other materials might be possible. The material chosen for the additional layer must fulfil the requirement of not being removed, or at a very low rate, during removal of material from the planar first layer.

Preferably, the additional layer is a polymer layer and the thickness of the polymer layer is 100 nm-50 μm, preferably 200 nm-1 μm. Such, a thickness of the polymer layer is suitable in that it is sufficient as a protective layer 16. Furthermore, such a thickness is sufficiently thin to provide good rigidity and to provide a stable support for the device layer.

The method may also comprise, after the step of removing material from the planar first layer under the elongated structure and before the step of removing material in the device layer to form the elongated structure, the step of performing additional processing steps including, photolithography and/or material deposition and/or thermal processing and/or surface functionalization and/or layer transfer processes and/or wet/dry etching processes.

It is also possible to perform additional process steps before the step of removing material from the planar first layer as long as said process steps and the materials used in them are compatible with the processes used in the method. For example, a metal may be deposited and structured on the device layer substrate before removing material from the planar first layer if the material removed from the planar first layer is a polymer and O2 plasma is used when removing the polymer below the device layer to form the support structure.

One embodiment is to enable the fabrication of an elongated structure supported on a support structure and together with additional structures requiring additional processing steps including, photolithography and/or material deposition and/or thermal processing and/or surface functionalization and/or layer transfer processes and/or wet/dry etching processes. The method makes this possible in case the additional steps are performed before the step of removing material in the device layer to form the elongated structure. This is due to the fact that the elongated structure is attached to the remainder of the device layer along the length of the elongated structure until the last step. Thus, in contrast to the methods according to the prior art no special care has to be taken when performing the additional processing steps. Also, no special care has to be taken when removing the material from the planar first layer to fabricate the support structure as this step is performed as the first step, before any additional structures have been formed.

The method may also comprise the step of removing material in the device layer to provide a second set of openings, wherein the first set of openings and the second set of openings are arranged on opposite sides of the elongated structure. Even though it is possible to form the support structure under the elongated structure using only one set of opening. It is preferable to have two sets of openings on opposite sides of the elongated structure as this provides better control of the fabrication of the support structure. With two sets of openings it is possible to fabricate the support structure centered under the elongated structure. In case an additional layer is arranged between the device layer and the planar first layer, the openings of the second set of openings are arranged also through the additional layer.

The planar first layer may comprise a base layer and an intermediate layer, wherein the support structure is formed in the intermediate layer. It is practical to have a base layer and an intermediate layer as this facilitates the fabrication of the support structure and also gives more freedom to the design of the device.

The ratio of the removed area in the intermediate layer to the total area of the openings through the device layer is at least 2, preferably 5. Preferably, the removal of material from the intermediate layer is performed in such a way that the support structure is separated from the surrounding intermediate layer. Thus, the area of the intermediate layer to be removed is predetermined. The area of the openings should be considerably smaller than the area of the removed intermediate layer.

The method may be directed to the fabrication of a waveguide. To this end the elongated structure may be arranged to be a waveguide for guiding an electromagnetic wave.

When the elongated structure is arranged to be a waveguide for guiding an electromagnetic wave the refractive index of the intermediate layer may be arranged to be different from the refractive index of the device layer. Such an arrangement of the refractive indices enables a favorable guiding of an electromagnetic wave with small losses.

The base layer may be a silicon layer, and the intermediate layer may be a silicon dioxide layer or a sapphire layer. Silicon dioxide and sapphire both have a refractive index in the infrared which is lower than the refractive index of silicon. This arrangement of the refractive indices will reduce optical losses from the waveguide to the support structure.

The intermediate layer may be a polymer layer. There are a number of advantages of using a polymer in the intermediate layer. The solvents that are used for removing the polymer are less aggressive than the normally used etchants. This makes the solvents compatible with many materials already on the wafer, which facilitates the fabrication of the device. Polymers can also be structured in a dry etching process with oxygen plasma. This process is also very mild and compatible with many standard materials in the semiconductor industry. Finally, the use of a polymer layer as the intermediate layer might reduce the optical losses from the waveguide to the support structure and might also reduce the cost of the device.

It is preferable to use an SOI (silicon on insulator) wafer as starting material so that the base layer is a silicon layer, the intermediate layer is a silicon dioxide layer and the device layer is a silicon layer. Such wafers are readily available which is advantageous.

As an alternative to what has been described above, the material in the device layer, the first layer and the intermediate layer may be chosen from the group of materials consisting of chalcogenide glass (ChGs), germanium, silicon germanium, silicon nitride, sapphire and, diamond. Depending on the application these materials may be advantageous.

Other materials that may be used are mentioned in the following list:
III-V materials, such as GaAs, InP, InGaAs, and InGaP
indium(III)-fluoride
lithium niobate and other nonlinear materials
piezoelectric materials
polymer
metals e.g. TiW, Ni, Au, W, Al, Cr, Ti, Cu, Ag
silicon carbide.

The thickness of the device layer may be arranged to be smaller than the wavelength to be guided. This is advantageous in that the waveguide then may be used to guide an electromagnetic wave, having a large portion of the energy propagating as an evanescent wave, with low levels of optical losses in the waveguide.

The width of the waveguide in the device layer is arranged to be at least 5 times the thickness of the device layer. By having this ration between the height and width of the waveguide. This will lead to the effect of the side surfaces on the electromagnetic being small in comparison with the effect of the top and bottom surfaces of the waveguide. This is advantageous in that the quality of the top and bottom surfaces may be fabricated with a considerably higher quality than the side surfaces. The material in the waveguide is preferably chosen to fit for a wavelength of the electromagnetic wave within the range of 0.4-100 μm, preferably 1.2-20 μm, and most preferred within 3-12 μm. Silicon is a suitable material for the wavelength range from 1.1 μm-10 μm while other materials from the materials mentioned above maybe more suitable for wavelengths below 1.1 μm and above 10 μm.

The arrangement of the first set of openings may be such that the support structure is formed as a number of spaced apart support pillars so that the elongated structure is free-hanging between the support pillars. By having the support structure in the form of spaced apart support pillars the effect of the support structure on the electromagnetic wave is minimized, i.e., the attenuation of the electromagnetic wave due to the support structure is minimized.

The width of the support structure/said at least one support pillar at the point of support of the elongated structure may be smaller than the width of the elongated structure. By having the width of the support structure/said at least one support pillar smaller than the width of the elongated structure the effect of the support structure on the electromagnetic wave is minimized, i.e., the attenuation of the electromagnetic wave due to the support structure is minimized.

With the method it is of course also possible to fabricate a device where the width of the support structure is larger than the width of the elongated structure. However, when the elongated structure is a waveguide this is not preferable as a wider support structure increases the optical losses from the waveguide to the support structure.

In order to fabricate the support structure, the shortest distance between the elongated structure and the openings in the first set of openings varies along the length of the elongated structure and said distance has a maximum at the support pillars. This is in the case that the elongated structure is fabricated with straight sides. By such an arrangement of the openings in the first set of openings the removal of material from the planar first layer by dissolution or etching will lead to the desired fabrication of support pillars as will be described in more detail below.

As has already been mentioned above the step of removing material from the planar first layer under the elongated structure is made by etching or dissolution. The step of removing material from the planar first layer under the elongated structure is performed during a predetermined time period, wherein the predetermined time period is dependent on the etch rate/dissolution rate of the etchant/solvent or the process parameters in plasma etching, and the arrangement of the openings in the device layer.

The openings in the first set of openings may have a smallest extension of no less than 10 nm and preferably no less than 100 nm. With such an extension of the openings a reliable removal of material may be secured. The largest extension of the holes is limited by the practical reasons. The elongated structure should not be free-hanging over too large distances as this would cancel the advantages of the method. The largest extension of the openings should not exceed 50 μm. In case the openings are circular they should not be larger than a few μm.

The method may also comprise the step of, before the step of forming the first set of openings, forming trenches in the device layer to define a rib waveguide in contact with the elongated structure. By forming trenches to define a rib waveguide a transition from a free-hanging waveguide to a rib waveguide may be formed. The inclusion of a rib waveguide makes it easier to connect light sources and detectors.

The method may also comprise the step of, after removing material from the planar first layer under the elongated structure through the first set of openings, sealing the first set of openings. In case also a second set of openings have been formed they are, naturally, also sealed. By sealing said openings a smooth surface is achieved. A smooth surface improves later processes on the device. The material used to seal said openings is preferable an easily removable material, as the sealing material has to be removed in a later stage, possibly after fabrication of additional structures on the device.

In addition to or as an alternative the method may also comprise the step of, after removing material from the planar first layer under the elongated structure through the first set of openings, the void under the elongated structure may be filled at least partly. By at least partly filling the void a better stability of the device layer is achieved.

The material used to seal said openings or to fill the void may be, e.g., a polymer, a photoresist, silicon nitride, silicon dioxide, alumina or a metal.

According to a second aspect of a device is provided, comprising a base layer; a support structure formed on the base layer; and a side structure formed on the base layer. The device also comprises an elongated structure, extending in a length direction in a device layer, the elongated structure having a width in the device layer in a direction perpendicular to the length direction, and a height in a direction out of the device layer and perpendicular to the length direction, being delimited by two side surfaces and being supported on the support structure, wherein at least a part of the side structure is arranged at a distance from the elongated structure in the width direction.

When manufacturing a device as described according to the first aspect the stress from the base layer around the elongated structure may have adverse effect. In particular, warpage of the base layer may bend the elongated structure in an unintended direction.

Removal of material from the intermediate layer changes the net stress of the base layer, especially in the case with a stack of different materials, which is the case for example for an SOI wafer. These changes in stress might lead to warpage of the base layer which might have an adverse effect on:

a) the processing possibilities of the substrate, since standard manufacturing processes such as materials deposition, photolithography, plasma processes and bonding require flat substrates.

If the warpage of the base layer exceeds a critical limit, these processes can only be performed with low yield (or not at all) on the base layer, which makes the manufacturing of these devices unprofitable (or unfeasible).

b) the elongated structure, especially if it is free-hanging since the separation of the free-hanging structure and the substrate might alter inadvertently. If the elongated structure is a waveguide, a reduced distance between waveguide and substrate leads to increased propagation loss of light traveling along the waveguide, which reduces the performance of the device or even makes it non-functional.

Most applications require packaging of the final device to protect them from environmental and mechanical influences. Attaching a capping substrate to the device (e.g. by bonding) is one feasible packaging technique. In this case, the capping substrate comprises voids to prevent direct contact of the capping substrate and the device. If the elongated structure is a waveguide, a large separation of the elongated structure and the substrate is beneficial for the device performance. However, with increasing separation, packaging becomes more challenging since the voids in the capping substrate are required to be larger. Furthermore, the attachment of the capping substrate to the device substrate might be a challenge since the fabrication of the device limits the choice of materials available as contact layer, which guarantees a proper attachment of the capping substrate to the device.

With the device according to the second aspect, the warpage of the substrate is reduced by the side structure, which controls the stress from the surrounding structures around the free hanging structure. The side layer reduces the adverse effect due to the intrinsic stress of the substrate and the stress of films adhering to the back surface of the substrate. By adjusting the film thickness and pattern density of the side layer, it is possible to provide a device having a substrate with small warpage.

The remaining material of the intermediate layer, which forms the side layer, decreases the height difference between elongated structure and a significant part of the device substrate. Therefore, the required depth of voids in a capping substrate is reduced. Also, the material of the side layer may be a preferred choice as contact layer. For example, in case of an SOI wafer, the revealed oxide layer is an excellent material for bonding to a capping substrate which is covered with oxide in the contact regions.

The material of the side structure may be different from the material of the base layer. The material in the side structure may then be optimized independently of the material in the base layer.

The material of the side structure may be different from the material in the device layer. The material in the side structure may then be optimized independently of the material in the device layer.

The material of the side structure may be of the same material as the support structure. This facilitates production of the side structure.

At least the side of the side structure facing away from the base layer may be free from contact with the device layer. This gives more freedom to optimization of the contact surface for a capping substrate.

The width of the support structure at the contact with the elongated structure may be smaller than the width of the elongated structure at least along a part in the length direction. This minimizes the losses of energy from an electromagnetic wave in the elongated structure.

The support structure may extends along only a part of the elongated structure such that there is a free-hanging portion of the elongated structure. This further reduces the losses of energy from an electromagnetic wave in the elongated structure.

The support structure may be formed as a number of spaced apart support pillars so that the elongated structure is free-hanging between the support pillars.

The minimum distance between the side structure and the elongated structure in the width direction is more than the maximum distance, perpendicularly to the base layer, between the elongated structure and the base layer. This also minimizes the losses of energy from an electromagnetic wave in the elongated structure.

In case any other layer is arranged on the base layer below the elongated structure the minimum distance between the side structure and the elongated structure in the width direction is more than the maximum distance, perpendicularly to the base layer, in the height direction between the elongated structure and said any other material.

The thickness of the side structure is at least 1/100, more preferably at least 1/10 or most preferably at least 1/100 of the thickness of the support structure. A larger thickness facilitates the attachment of a capping substrate.

The side structure may be physically separated from the support structure. This also reduces the losses of energy from an electromagnetic wave in the elongated structure.

The device may comprise a connection layer on the base layer between the support structure and the side structure. It is possible to control the stress and warpage of the substrate with such a connection layer as such a connection layer improves the rigidity of the device.

The connection layer may be of the same material as the support structure or the side structure. One advantage of this embodiment is that the interface between connection layer and support structure/side structure is more mechanically stable, and thus conveys the stress/force between those two components better. Different materials have a weaker interface which might result in cracks/breakage and a worse distribution of stress on the substrate. This facilitates the manufacturing of the device as the number of different materials becomes limited.

The connection layer may be connected to at least one of the support structure and the side structure. This has the same advantage as the feature of having the same material in the connection layer as in the support structure or the side structure.

The connection layer may be positioned under one of the side surfaces. In this way the rigidity of the device may be optimized.

The thickness of the connection layer may be smaller than the thickness of the support structure. If the connection layer is of the same material as the support structure this is a required limitation. Advantageously material should not be close to the elongated structure. This is the main reason for manufacturing the support structure separated from the side structure.

The thickness of the connection layer may be smaller than the thickness of the side structure. In case the material in the side structure is the same as the material in the connection layer this requirement is necessary.

The maximum thickness of the connection layer may be at most ½, preferably at most 1/10, and most preferably at most 1/100. A thinner connection layer may have less negative effect on the elongated structure than a thicker connection layer when the connection layer is close to the elongated structure in the width direction.

The thickness of the side structure is larger than the maximum thickness of the connection layer. This makes it easier to attach a capping substrate on the device.

The edge of the elongated structure and the edge of the support structure may be at least partially nonparallel in a plan view. Thus, when the elongated structure is a waveguide, the width of the support structure may vary independently from the width of the waveguide. This allows the design of support structures with lower propagation loss. The propagation loss of a straight waveguide with a pillar underneath is lower than for a waveguide with a varying width.

### BRIEF DESCRIPTION OF THE DRAWINGS

In the following embodiments of the invention will be described with reference to the appended drawings.

FIG. 1 shows the starting material for fabrication of a device of a method according to an embodiment;

FIG. 2 shows the starting material with a first set of openings formed through the device layer;

FIG. 3 shows the device after material has been removed from the planar first layer and after the elongated structure has been separated from the device layer;

FIGS. 4a and 4b illustrate a device fabricated with a method according to an alternative embodiment;

FIGS. 5-8 illustrate a method according to an alternative embodiment;

FIG. 9 is a cross-sectional view of the elongated structure and the support structure;

FIG. 10a shows schematically in cross section a structure in which the first set of openings and the second set of openings have been sealed;

FIG. 10b shows schematically in cross section a structure after the void under the elongated structure has been partly filled;

FIG. 11a shows a structure with an additional layer between the planar first layer and the device layer after material has been removed from the planar first layer;

FIG. 11b shows a structure with an additional layer between the intermediate layer and the device layer after material has been removed from the intermediate layer;

FIG. 12a shows in cross section the structure of FIG. 11a in which parts of the additional layer have been removed;

FIG. 12b shows in cross section the structure of FIG. 11b in which parts of the additional layer have been removed;

FIG. 13 shows, in a top view, a first set of openings and a second set of openings, according to an alternative embodiment;

FIG. 14 is a flow diagram of a method according to an embodiment; and

FIG. 15 is a cross-sectional view of the elongated structure and the support structure according to an alternative to the cross section shown in FIG. 9.

### DETAILED DESCRIPTION OF ILLUSTRATIVE EMBODIMENTS

In the following description of embodiments the same reference numerals will be used for similar features in the different drawings. The drawings are not drawn to scale.

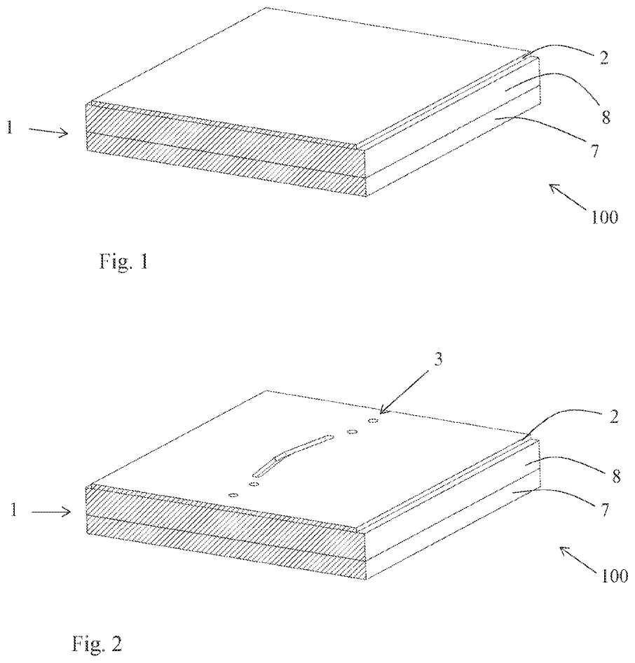

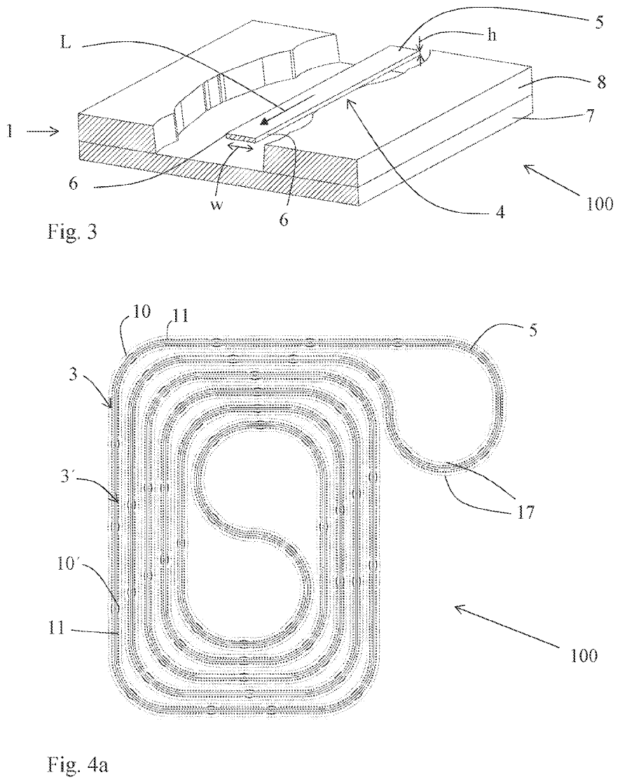

FIGS. 1-3 illustrate a method according to an embodiment for fabrication of a device with an elongated structure. The method is directed to the fabrication of a device 100 with an elongated structure 5 as is shown in part in FIG. 3. The elongated structure 5 extends in a length direction L in a device layer 2. The elongated structure 5 has a width w (FIG. 3) in the device layer 2 in a direction perpendicular to the length direction L, and a height h (FIG. 3) in a direction out of the device layer 2 and perpendicular to the length direction L. The elongated structure 5 is delimited by two side surfaces 6 and is supported on a first layer 1 by a support structure 4.

The starting material for the method is in the form of a planar first layer 1 on which a device layer 2 is arranged, as shown in FIG. 1. The planar first layer 1 comprises a base layer 7 and an intermediate layer 8.

In a first step material in the device layer 2 is removed to provide a first set of openings 3 through the device layer 2. FIG. 2 shows the planar first layer 1, comprising the base layer 7 and the intermediate layer 8, with a first set of openings 3 formed through the device layer 2. Depending on the material in the device layer 2 the first set of openings 3 may be formed using etching or dissolution.

In a second step material from the planar first layer 1 under the elongated structure 5 is removed through the first set of openings 3. The arrangement of the first set of openings 3 is such that a support structure 4 is formed. The removal of the material from the first layer 1 is performed using etching or dissolution depending on the material in the first layer. The different materials that may be used will be discussed in more detail below. In a third step material in the device layer 2 is removed to form the elongated structure 5 delimited by the side surfaces 6, as is shown in FIG. 3. The elongated structure 5 extends in the length direction L.

The step of removing material from the planar first layer 1 under the elongated structure 5 is made by etching or dissolution. A number of different etching techniques exist such as wet etching, dry etching and plasma etching. The step of removing material from the planar first layer 1 under the elongated structure 5 is performed during a predetermined time period. The predetermined time period is dependent on the etch rate/dissolution rate of the etchant/solvent or the process parameters in plasma etching, and the arrangement of the openings 3 in the device layer 2.

FIGS. 4a and 4b illustrate the fabrication of a device 100 with a method according to an alternative embodiment. FIG. 4a shows schematically the device 5 before the elongated structure 5 has been separated from the device layer 2. As can be seen in FIG. 4 the elongated structure 5 is formed as a closed loop in a double spiral. The arrangement of the elongated structure 5 as a closed loop enables the elongated structure 5 to be long in a small space. A first set of openings 3 and a second set of openings 3′ have been formed through the device layer 2 on opposite sides of the elongated structure 5. The first set of openings 3 comprises circular openings 11 and elongated openings 10. Similarly, the second set of openings 3 comprises circular openings H and elongated openings 10′. The cavity formed by removal of material from the intermediate layer 8 (FIGS. 1-3) is shown with the dotted lines 17. FIG. 4b shows the device 100 after the elongated structure 5 has been separated from the device layer 2 (FIGS. 1-3). If made by a suitable material the elongated structure 5 can be a waveguide. Coupling of light into and out of the elongated structure 5 can be performed with gratings (not shown) arranged on the surface of the elongated structure.

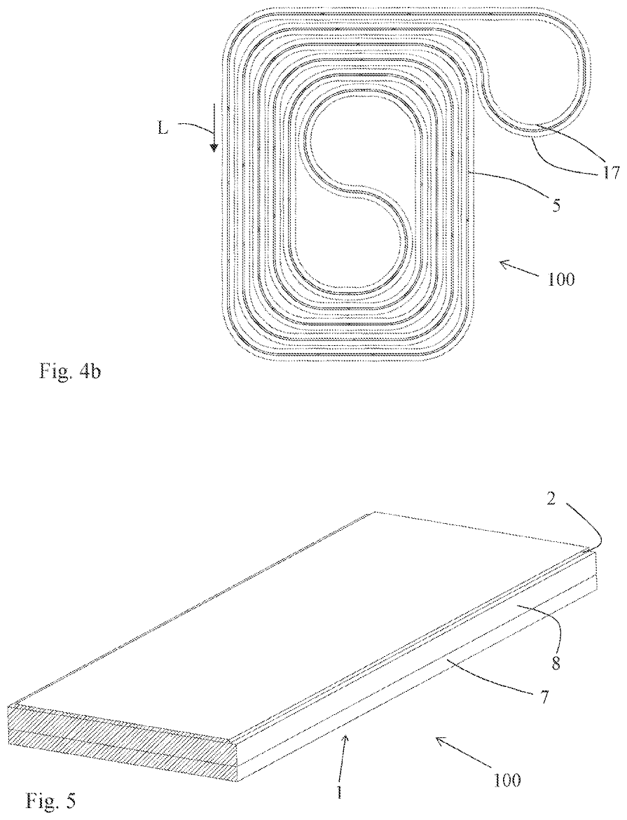

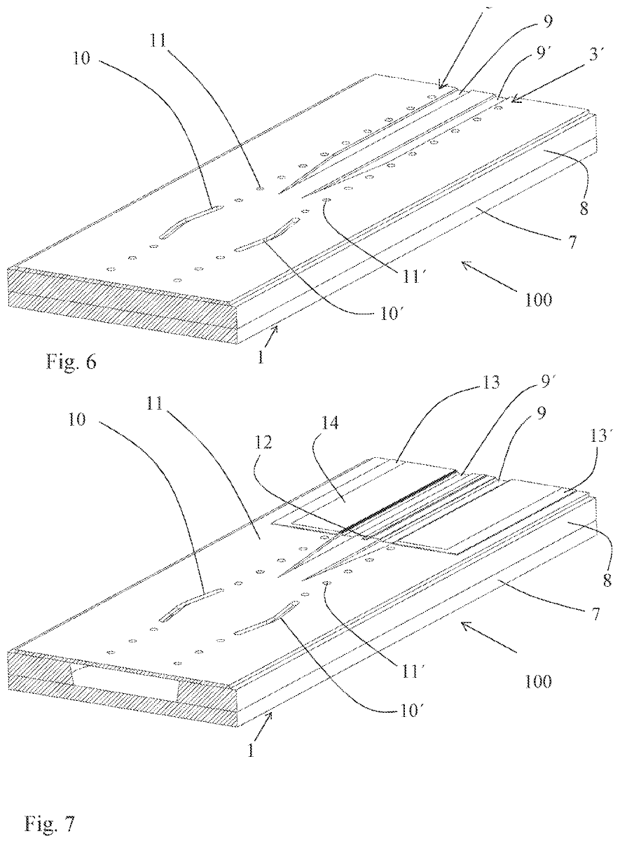

FIGS. 5-8 illustrate a method according to an alternative embodiment. FIG. 5 shows in a perspective view in cross section a planar first layer 1 on which a device layer 2 is arranged. The planar first layer 1 comprises a base layer 7 and an intermediate layer 8. In FIGS. 5-8 the base layer 7 is shown to be equally thick as the intermediate layer 8 for illustrative reasons. However, normally the base layer 7 is considerably thicker than the intermediate layer 8. In a first step two trenches 9, 9′, are formed in the device layer 2. In a second step material is removed from the device layer 2 to provide a first set of openings 3 and a second set of openings 3′. The resulting structure after the first step and the second step is shown in FIG. 6. The first set of openings 3 and the second set of openings 3′ are arranged on opposite sides of the elongated structure (not shown in FIG. 6). As can be seen in FIG. 6 the first set of openings 3 comprises a first elongated opening 10. The first elongated opening 10 is slightly V-formed with the tip of the V pointing away from the support structure 4 to be formed. Correspondingly, the second set of openings 3′ comprises a second elongated opening 10′ which is slightly V-formed with the tip of the V pointing away from the support structure 4 to be formed. The openings 11, 11′, as shown in FIG. 6 have circular shape. This increases the stability of the device layer 2 by preventing corners with high stress in the device layer 2. The openings 10, 10, ′11, 11′, must be sufficiently large to allow the etchant/solvent/radicals (in case of plasma etching) to penetrate through the device layer 2. The openings 10, 10′, 11, 11′, do not have to be very large. In fact, even openings 10, 10′, 11, 11′, with a diameter of a few tens or a few hundreds of nanometers can be used. Decreased hole size might allow easier processing in the following steps. The other openings in the first set of openings 3 and the second set of openings 3′ are circular openings 11, 11′. The size of the elongated openings 10, 10′, and the circular openings 11, 11′, is chosen so that an efficient removal of material may be performed through the openings 10, 10′, 11, 11′. The elongated openings 10, 10′, and the circular openings 11, 11′, have a smallest extension of no less than 10 nm and preferably no less than 100 nm. In some cases, it might be beneficial that the elongated openings 10, 10′, and the circular openings 11, 11′, in the device layer 2 also define the edge of the elongated structure 5 to be formed. Meaning, the distance between an opening 10, 10′, 11, 11′, and the elongated structure 5 can decrease to zero.

After formation of the first set of openings 3 and the second set of openings 3′ material is removed from the intermediate layer 8. Depending on the material in the intermediate layer 8 the removal of material from the intermediate layer is performed in different ways. The material may be removed through etching or dissolution using a solvent. There are a number of different etching techniques, known per se to a person skilled in the art, that may be used for removing material from the intermediate layer. These etch techniques can have an isotropic or anisotropic etch profile. After the step of removing material from the intermediate layer 8 under the elongated structure 5 additional processing steps including, photolithography and/or material deposition and/or thermal processing and/or surface functionalization and/or layer transfer processes and/or wet/dry etching processes are performed before the elongated structure 5 is separated from the device. The elongated structure 5 extends in the length direction L and is delimited on the sides by the side surfaces 6. FIG. 7 shows the resulting structure after removal of material from intermediate layer 8. The ratio of the removed area in the intermediate layer 8 to the total area of the openings 10, 10′, 11, 11′, through the device layer 2 is at least 2, preferably 5. In this way, the openings 10, 10′, 11, 11′, may have a limited size which is advantageous for mechanical stability of the device layer 2, as the material in the device layer 2 between the openings 10, 10′, 11, 11′, may be wider with smaller openings 10, 10′, 11, 11′. As can be seen in FIG. 7 a metal rib 12 in the form of a metal electrode has been formed on top of the device layer 2 between the trenches 9, 9′. Also, a first metal layer 13 and a second metal layer 13′ have been formed as electrodes on opposite sides of the trenches 9, 9′. Finally, a stack 14 of a two-dimensional material e.g. graphene and a passivation layer are transferred on top of the first metal layer 13, the second metal layer 13′, the trenches 9, 9′ and the metal rib 12. A rib waveguide is formed by the elongated structure 5 between the trenches 9, 9′, and the metal rib 12.

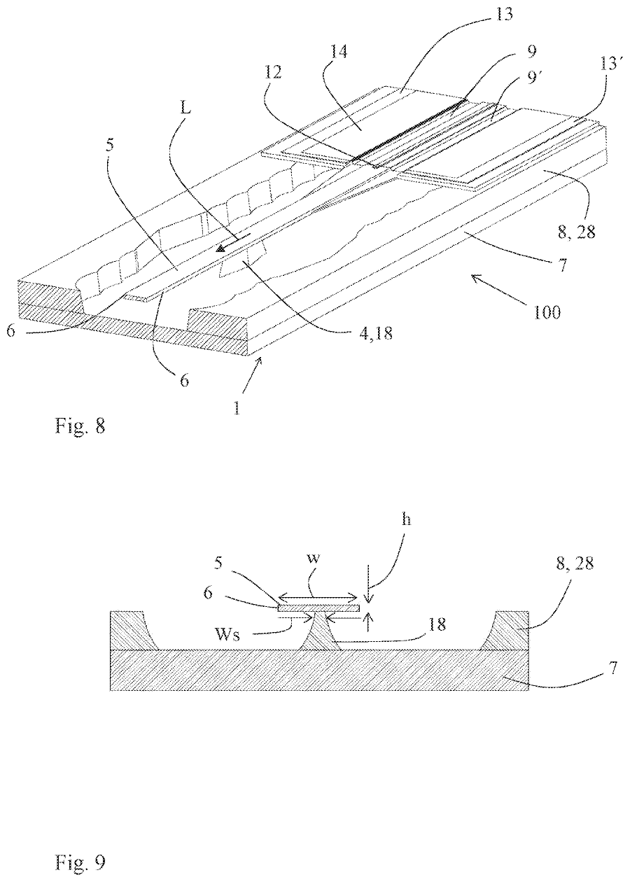

In a final step material is removed from the device layer 2 to form the elongated structure 5 delimited by side surfaces 6. The resulting structure can be seen in FIG. 8. The elongated structure 5 in the device 100 in FIG. 8 is a waveguide. In FIG. 8 it is seen that the elongated structure 5 in the form of a waveguide transits into a rib waveguide formed by the elongated 5 structure 5 between the trenches 9, 9. In the transition portion the thinned portion of the

device layer 2 widens. These thinned portions of the device layer 2 were formed as the trenches 9, 9′, in FIG. 6. In FIG. 8 the support structure 4 is in the form of a support pillar 18. As can be seen in FIG. 8 the support pillar 18 has a diamond shape which reflects the shape of the first elongated opening 10 and the second elongated opening 10′. The removal of material in the intermediate layer 8 takes place through the openings 10, 10′, 11, 11′. The void grows over time as the etching/dissolution continues. The size of the void depends on the etch rate/dissolution rate of the etchant/solvent step and the time of etching/dissolution. Thus, in order to control the removal of material from the intermediate layer 8 it is necessary to control the etch/dissolution rate as well as the time of etching/dissolution. The etching/dissolution is performed during a predetermined time period, wherein the predetermined time period is dependent and the arrangement of the openings 10, 10′, 11, 11′, in the device layer 2. The final edges of the void in the intermediate layer 8 is the etching front which is at a specific distance from the closest opening in the first set of openings 3 and the second set of openings 3′. If the etching/dissolution would have been allowed to continue the support pillar 18 would have become increasingly shorter. Simultaneously, the support structure would have become narrower.

In FIG. 8 only one support pillar 18 is shown but naturally the device fabricated with the method according an embodiment may comprise a number of support pillars 18 with the elongated structure 5 free-hanging between the support pillars 18. The shortest distance between the elongated structure 5 and the openings 10, 11, in the first set of openings 3 varies along the length of the elongated structure 5 and said distance has a maximum at the support pillars 18. Naturally, the distance between the elongated structure 5 and the openings 10, 11, in the first set of openings 3 is not clearly visible as the elongated structure 5 is not clearly visible until the elongated structure 5 has been separated from the surrounding device 30 layer 2.

When the elongated structure 5 is a waveguide the refractive index of the intermediate layer 8 is arranged to be different from the refractive index of the device layer 2. In FIGS. 5-8 the base layer 7 is a silicon layer, and the intermediate layer 8 is a silicon dioxide layer. Alternatively, the intermediate layer may be a sapphire layer, or a polymer layer. Additionally, the intermediate layer can be of chalcogenide glass (ChGs), germanium, silicon germanium, silicon nitride and, diamond. In case the intermediate layer is a polymer layer the removal of material from the intermediate layer may be performed by dissolution using a solvent. It is also possible to remove material from the intermediate layer by plasma etching using an oxygen plasma.

The device layer 2 may be a silicon layer. It is preferable to use a structure of silicon as base layer 7, silicon dioxide as intermediate layer 8 and silicon as device layer 2 as such substrates are readily available from a number of manufacturers. This makes the price on the starting material low. Such substrates are usually marketed under the abbreviation SOI (silicon on insulator).

It is of course also possible to choose other materials for the device layer 2, the first layer and the intermediate layer such as, e.g., a material from the group of materials consisting of chalcogenide glass (ChGs), germanium, silicon germanium, silicon nitride, sapphire and, diamond.

It is possible to use a polymer in the intermediate layer 8. In such a case, it is possible to use a solvent to remove material from the intermediate layer 8. Solvents used to dissolve polymers are considerably less aggressive than etchants used to remove silicon. Thus, metals can be deposited before removing a polymer below the device layer 2. Similarly, a deposited layer of silicon is not attacked when removing SiO₂ below the device layer 2 with hydrofluoric acid. It is also possible to remove material from the intermediate layer 8 by plasma etching using an oxygen plasma.

When the elongated structure 5 is used as a waveguide the thickness of the device layer 2 is arranged to be smaller than the wavelength to be guided. Furthermore, the width of the waveguide in the device layer 2 is arranged to be at least 5 times the thickness of the device layer 2. It is favorable to have the width of the waveguide at least 5 times the thickness as the side surfaces 6 cannot be made with the same quality as the top and bottom surfaces. Thus, by making the waveguide wide the effect of the side surfaces 6 on the wave guiding properties is minimized.

The wavelength of the electromagnetic wave is within the range of 0.4-100 μm, preferably 1.2-20 μm, most preferred within 3-12 m. Silicon is a suitable material for the wavelength range from 1.1-10 μm while other materials from the materials mentioned above may be more suitable for wavelengths below 1.1 μm and above 10 μm. A support structure 4 made from silicon dioxide has very little effect on an electromagnetic wave propagating in the waveguide.

In order to minimize the effect of the support pillar 18 on the electromagnetic wave propagating in the waveguide it is desirable to have the width of the support pillar 18 smaller than the width of the elongated structure 5 at the point of support of the elongated structure. This is clearly shown in the cross-sectional view of the elongated structure 5 with side surfaces 6 and the support structure 4 of FIG. 9. In FIG. 9 it is clearly shown that the width Ws of the support pillar 18 is considerably smaller than the width w of the elongated structure 5. The cross section in FIG. 9 is taken at the center of the support pillar 18 in FIG. 8. The features in the background, behind the plane of the cross section, are not shown in FIG. 9.

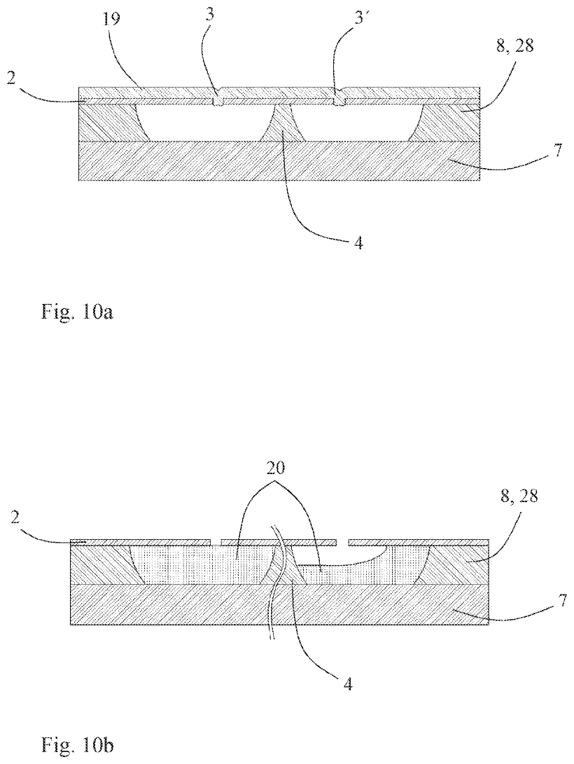

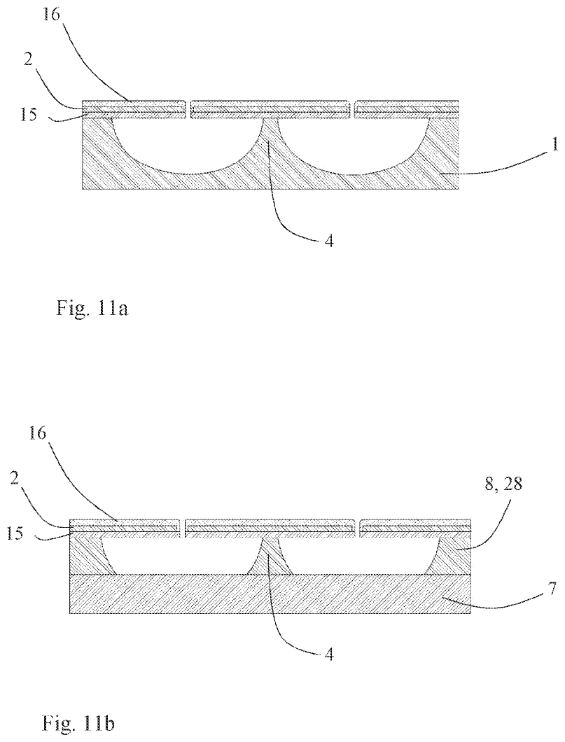

As described above the material in the intermediate layer 8 may be removed before any additional process steps for forming, e.g., additional layers on the device layer 2. In order to optimize such later processes it is favorable to seal the openings 10, 11, in the first set of openings 3 and the second set of openings 3′, before performing said additional process steps. In FIG. 10a the openings 3, 3′, have been sealed by application of a sealing layer 19 on the device layer 2. Such a structure with sealed openings 10, 11, in the first set of openings 3 and the second set of openings 3′ is shown schematically in FIG. 10a. In case an easily removable material such as, e.g., a polymer is used, the material in the intermediate layer 8 may be removed after additional process steps.

In order to increase the stability of the device layer 2 after removing material from the intermediate layer 8 under the elongated structure 5, the void under the elongated structure 5 can be filled at least partly as is shown in FIG. 10b. The filling material 20 is preferably an easily dissolved/removable material such as a polymer or a photoresist. FIG. 10b is split to show to different variants of the filling. In the left part of FIG. 10b the filling supports the entire device layer 2 under which the intermediate layer 8 has been removed.

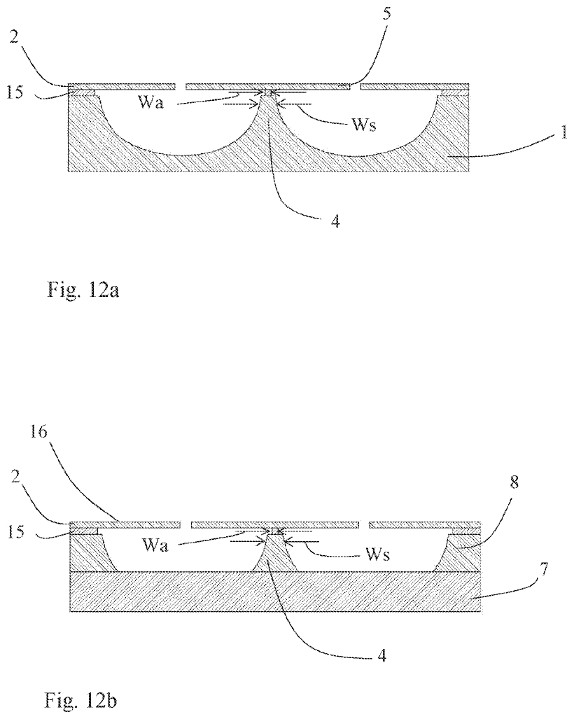

In some cases, it might be desirable to have the same material in the device layer 2 and the intermediate layer 8 or the planar first layer. Naturally this is very difficult to achieve without an additional layer. Thus, in order to allow the device layer 2 and the intermediate layer 8 to be of the same material an additional layer 15 may be added between the device layer 2 and the intermediate layer 8/planar first layer 1. The openings 10, 10′, 11, 11′, of the first set of openings 3 and the second set of openings 3 are arranged also through the additional layer 15. Before starting etching/dissolution of the intermediate layer 8/planar first layer 1, a protective layer 16 is arranged on the upper side of the device layer 2. FIG. 11a shows the structure after material has been removed from the planar first layer 1. The additional layer 15 is almost unaffected by the etching/dissolution and covers the underside of the elongated structure 5. The removal of material from the additional layer 15 must be sufficiently slower than the removal of material from the planar first layer 1 so that the device layer 2 is protected during etching. Similarly, the protective layer 16 is almost unaffected by the etching/dissolution and is intact on the upper side of the elongated structure. The protective layer 16 and the additional layer 15 may be of the same material such as, e.g., a polymer. The thickness of the additional layer 15 is 100 nm-50 μm. The addition of an additional layer 15 in the form of a polymer layer can reduce optical losses in the waveguide further. In FIG. 11a the support structure 4 is formed in the planar first layer. In FIG. 11b the planar first layer 1 comprises a base layer 7 and an intermediate layer 8. Another example of a structure with the same material in the device layer 2 and the intermediate layer 8 is a SOI (silicon on insulator) structure. An SOI wafer is then used as starting material so that the base layer 7 is a silicon layer, the intermediate layer 8 is a silicon dioxide layer and the device layer 2 is a silicon layer. Such a structure would result in a device with the same structure as is shown in FIGS. 11a and 12a.

When material has been removed from the intermediate layer 8/planar first layer 1, the protective layer 16 and parts of the additional layer 15 may be removed. In this case the protective layer 16 and parts of the additional layer 15 are polymer layers and are removed with a suitable solvent or plasma etching. The thickness of the polymer layer is 100 nm-50 μm, preferably 200 nm-1μ. The resulting structures are shown in in cross section in FIGS. 12a and 12b with the same reference numerals as in FIGS. 11a and 11b. In FIGS. 12a and 12b it can be clearly seen that the width Wa of the additional layer 15 is smaller than the width of the support structure 4 Ws at the top of the support structure 4.

With this method it is also possible to fabricate a device where Ws is larger than the width w of the elongated structure 5. However, to reduce optical losses through the support, it is beneficial to minimize the size of the support structure.

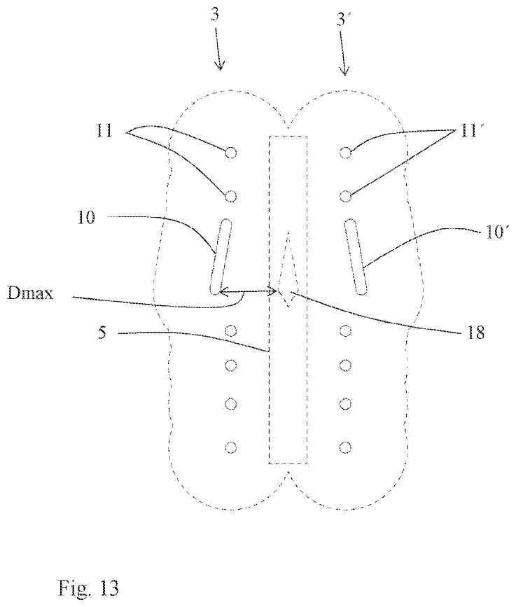

FIG. 13 shows, in a top view, a first set of openings 3 and a second set of openings 3′, according to an alternative embodiment. In FIG. 13 the elongated openings 10, 10′ have a straight shape but are arranged at an angle to the elongated structure 5. The resulting support pillar 18 is shown with dashed lines in FIG. 13. The arrangement of the elongated openings 10, 10′, is reflected in the shape of the support pillar 18 which is wedge shaped in FIG. 13. The elongated structure 5 is free-hanging on both sides of the support pillar 18.

It would of course be possible to replace the elongated openings 10, 10′, with a number of closely spaced circular openings 11, 11′. However, elongated openings 10, 10′, give smoother walls on the support structure 4. Abrupt edges on the support structure 4 may cause reflections in case the elongated structure 5 is a waveguide.

The shortest distance between the elongated structure 5 and the openings 10, 11, in the first set of openings 3 varies along the length of the elongated structure 5 and said distance has a maximum Dmax where the width of the support pillar 18 is at its maximum.

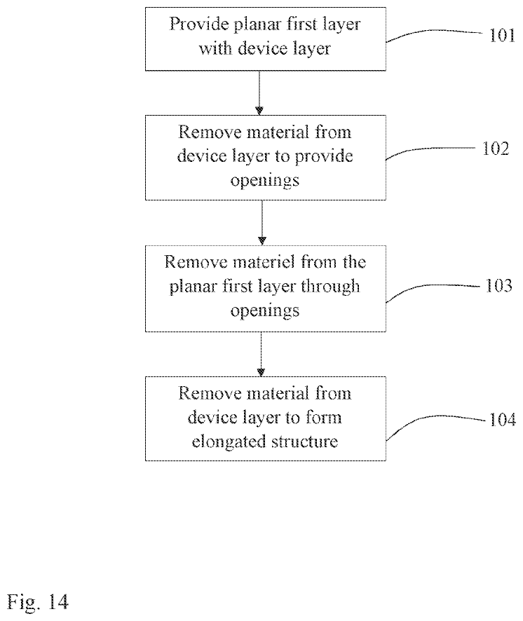

FIG. 14 is a flow diagram of a method according to an embodiment. In a first step 101 a planar first layer 1 is provided on which first layer 1 a device layer 2 is supported. In a second step 102 material is removed from the device layer 2 to provide a first set of openings 3 through the device layer 2. In a third step 103 material is removed from the planar first layer 1 under the elongated structure 5 through the first set of openings 3, wherein the arrangement of the first set of openings 3 is such that a support structure 4 is formed on which the elongated structure 5 is supported. In a fourth step 104 material is removed from the device layer 2 to form the elongated structure 5 delimited by the side surfaces 6.

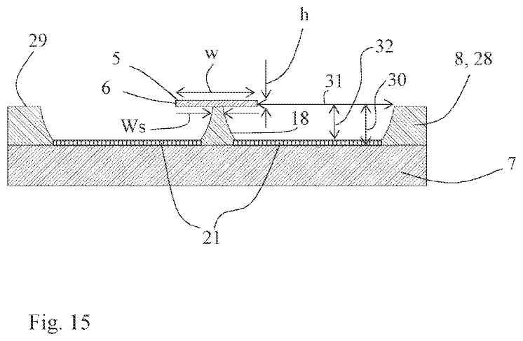

FIG. 15 is a cross-sectional view of the elongated structure and the support structure according to an alternative to the cross section shown in FIG. 9. The difference between FIG. 15 and FIG. 9 is that the device comprises a connection layer 21 which is in contact with the base layer 7 and extends between the support structure 4 and the side structure 28.

The material of the side structure 28 may be different from the material of the base layer 7 and also different from the material of the device layer 2. However, in order to facilitate the production of the device the material of the connection layer is preferably the same as the material of the side structure. The side structure 28 is physically separated from the support structure 4.

As can be seen in FIG. 15 the side 29 of the side structure 28 facing away from the base layer 7 is free from contact with the device layer 2.

It can also be seen in FIG. 15 that the width of the support structure 4 at the contact with the elongated structure 5 is smaller than the width of the elongated structure 5 at least along a part in the length direction.

The minimum distance 31 between the side structure 28 and the elongated structure 5 in the width direction is more than the maximum distance 30, perpendicularly to the base layer, between the elongated structure 5 and the base layer 7, and also more than the maximum distance 32 between the elongated structure 5 and any material.

The thickness 31 of the side structure 28 is about the same as the thickness 30 of the support structure 4. This allows easy arrangement of a capping substrate on the side structure 28.

The thickness of the side structure 28 is larger than the maximum thickness of the connection layer 21.

As can be seen in FIG. 8 the edge of the elongated structure 5 and the edge of the support structure 4 are at least partially nonparallel in a plan view.

The embodiments described above may be amended in many ways without departing from the scope of the present invention.

1.-47. (canceled)

48. A method for fabricating a device with an elongated structure extending in a length direction in a device layer, wherein the elongated structure has a width in the device layer in a direction perpendicular to the length direction and a height in a direction out of the device layer and perpendicular to the length direction, and wherein the elongated structure is delimited by two side surfaces and supported on a planar first layer by a support structure, the method comprising:
providing the planar first layer on which the device layer is supported;
removing a material in the device layer to provide a first set of openings through the device layer;
removing a material by etching or dissolution from the planar first layer under the elongated structure through the first set of openings, wherein an arrangement of the first set of openings is such that the support structure is formed on which the elongated structure is supported; and
removing the material from the device layer to form the elongated structure delimited by the side surfaces.

49. The method according to claim 48, further comprising arranging an additional layer between the device layer and the planar first layer, wherein the openings of the first set of openings are also arranged in the additional layer, and wherein the additional layer is a protective layer while removing the material from the planar first layer under the elongated structure.

50. The method according to claim 48, further comprising removing the material in the device layer to provide a second set of openings, wherein the first set of openings and the second set of openings are arranged on opposite sides of the elongated structure.

51. The method according to claim 48, wherein the planar first layer comprises a base layer and an intermediate layer, and wherein the support structure is formed in the intermediate layer.

52. The method according to claim 48, wherein the elongated structure is a waveguide for guiding an electromagnetic wave.

53. The method according to claim 52, wherein a thickness of the device layer is smaller than a wavelength to be guided.

54. The method according to claim 48, wherein the arrangement of the first set of openings is such that the support structure is formed as a number of support pillars being spaced apart so that the elongated structure is free-hanging between the support pillars.

55. A device comprising:
a base layer;
a support structure formed on the base layer;
a side structure formed on the base layer; and
an elongated structure extending in a length direction in a device layer,
wherein the elongated structure has a width in the device layer in a direction perpendicular to the length direction and a height in a direction out of the device layer and perpendicular to the length direction,
wherein the elongated structure is delimited by two side surfaces and is supported on the support structure, and
wherein at least a part of the side structure is arranged at a distance from the elongated structure in a width direction.

56. The device according to claim 55, wherein a width of the support structure at a contact with the elongated structure is smaller than the width of the elongated structure at least along a part in the length direction.

57. The device according to claim 55, wherein a minimum distance between the side structure and the elongated structure in the width direction is more than a maximum distance, perpendicularly to the base layer, between the elongated structure and the base layer.

58. The device according to claim 55, wherein a minimum distance between the side structure and the elongated structure in the width direction is more than a maximum distance, perpendicularly to the base layer, in a height direction between the elongated structure and any other material.

59. The device according to claim 55, wherein a thickness of the side structure is at least 1/100 of a thickness of the support structure.

60. The device according to claim 55, wherein the side structure is physically separated from the support structure.

61. The device according to claim 55, further comprising a connection layer located on the base layer between the support structure and the side structure.

62. The device according to claim 61, wherein the connection layer is of the same material as the support structure or the side structure.

63. The device according to claim 61, wherein the connection layer is connected to at least one of the support structure or the side structure.

64. The device according to claim 61, wherein the connection layer is positioned under one of the side surfaces.

65. The device according to claim 61, wherein a thickness of the connection layer is smaller than a thickness of the support structure.

66. The device according to claim 61, wherein a thickness of the connection layer is smaller than a thickness of the side structure.

67. The device according to claim 61, wherein an edge of the elongated structure and an edge of the support structure are at least partially nonparallel in a plan view.
